(19) United States
(12) Patent Application Publication
(10) Pub. No.: US 2018/0037983 A1
(43) Pub. Date: Feb. 8, 2018

(54) SPUTTERING DEVICE

(71) Applicant: TOPCON CORPORATION, Itabashi-ku, Tokyo (JP)

(72) Inventors: Masahiro AKIBA, Itabashi-ku, Tokyo (JP); Yoshihiro YAMAGUCHI, Itabashi-ku, Tokyo (JP); Makoto SETA, Itabashi-ku, Tokyo (JP)

(73) Assignee: TOPCON CORPORATION, Itabashi-ku, Tokyo (JP)

(21) Appl. No.: 15/554,841

(22) PCT Filed: Mar. 7, 2016
(86) PCT No.: PCT/JP2016/057015

§ 371 Date: Aug. 31, 2017

(30) Foreign Application Priority Data
Mar. 11, 2015 (JP) 2015-048191

(51) Int. Cl. C23C 14/34; H01J 37/34; H01L 21/677; C23C 14/54; C23C 14/50

(52) U.S. Cl. CPC C23C 14/34; C23C 14/548; C23C 14/50; H01L 21/677; H01J 37/3447; H01J 37/3414; G11B 7/265

(57) ABSTRACT

A sputtering device capable of satisfying various requirements is provided. The sputtering device includes a rotation and revolution table, multiple sputtering targets, an RF plasma source, and a load-lock chamber 102. The rotation and revolution table is arranged inside a pressure-reducible container 101 and is rotatable by independent control. The multiple sputtering targets are arranged on a revolution orbit of the rotation and revolution table so as to correspond to multiple workpieces 107 to be set on the rotation and revolution table. The RF plasma source performs plasma treatment. The load-lock chamber 102 is used for setting the multiple workpieces on the rotation and revolution table. The rotation and revolution table is configured by arranging multiple rotation mounts 105 on a revolution table 104, and the rotations of the revolution table 104 and the multiple rotation mounts 105 are independently controllable.

### TECHNICAL FIELD

The present invention relates to a sputtering device.

### BACKGROUND ART

Publicly known technologies for a sputtering device for improving film quality and processing efficiency are disclosed in Japanese Unexamined Patent Applications Laid-Open Nos. 11-335835, 2011-026652, 2003-183825, 7-307239, 10-317135, 2001-026869, and 2005-325433. For example, Japanese Unexamined Patent Application Laid-Open No. 10-317135 discloses a technique of depositing a film while a rotating workpiece revolves.

Optical components have various types of thin films deposited thereon in accordance with required optical characteristics. Optical components must be able to be made in a wide variety of small batch productions, in mass production of a few types, and in production for special severe-use environments, or for other requirements. Although techniques capable of satisfying any of these requirements are desired, conventional techniques have limited versatility.

### DISCLOSURE OF THE INVENTION

In view of these circumstances, an object of the present invention is to provide a sputtering device capable of satisfying various requirements.

A first aspect of the present invention provides a sputtering device including a rotation and revolution table, multiple sputtering targets, and a load-lock chamber. The rotation and revolution table is positioned in a pressure-reducible container and is rotatable by independent control. The multiple sputtering targets are placed on a revolution orbit of the rotation and revolution table so as to correspond to multiple workpieces to be set on the rotation and revolution table. The load-lock chamber is used for setting the workpieces on the rotation and revolution table. The rotation and revolution table is configured by arranging multiple rotation mounts on a revolution table. The rotations of the revolution table and the multiple rotation mounts are independently controllable.

According to a second aspect of the present invention, in the invention according to the first aspect of the present invention, the multiple sputtering targets may be configured to be used in respective film depositing atmospheres that are separated from each other in the pressure-reducible container.

According to a third aspect of the present invention, in the invention according to the first or the second aspect of the present invention, the sputtering device may perform sputtering while the rotation mounts rotate and the revolution table swings back and forth on the revolution orbit.

According to a fourth aspect of the present invention, in the invention according to any one of the first to the third aspects of the present invention, the sputtering device is configured so that multiple carriers on which workpieces are mounted are placed in the load-lock chamber and so that the multiple carriers are rotated and revolved in different manners.

According to a fifth aspect of the present invention, in the invention according to any one of the first to the fourth aspects of the present invention, the load-lock chamber may be controlled independently from the pressure-reducible container so as to be reduced in pressure.

According to a sixth aspect of the present invention, in the invention according to any one of the first to the fifth aspects of the present invention, the sputtering device may further include a plasma source or a radical source provided on the revolution orbit of the rotation and revolution table, to perform plasma treatment or radical treatment on the multiple workpieces to be arranged on the rotation and revolution table.

### Effects of the Invention

The present invention provides a sputtering device capable of satisfying various requirements.

### BRIEF DESCRIPTION OF THE DRAWINGS

FIG. 1 is a conceptual drawing of a sputtering device as seen from above.

FIG. 2 is a conceptual drawing of a sputtering device as seen from a side.

FIG. 3 is a conceptual drawing of an inside of a pressure-reducible container as seen from above.

FIG. 4 is a conceptual drawing showing an example of an operation mode.

FIG. 5 is a conceptual drawing showing an example of an operation mode.

FIG. 6 is a conceptual drawing showing a driving mechanism.

FIG. 7 is a conceptual drawing showing a structure of a sputtering section.

FIG. 8 is a conceptual drawing showing a structure of a sputtering section.

### EXPLANATION OF REFERENCE NUMERALS

100 denotes a sputtering device, 101 denotes a pressure-reducible container, 102 denotes a load-lock chamber, 104 denotes a revolution table, 105 denotes a rotation mount, 106 denotes a carrier, 107 denotes a workpiece, 108 denotes a sputtering section, 109 denotes a sputtering section, 110 denotes a plasma processing section, 111 denotes a sputtering target, 112 denotes a high frequency power source, 113 denotes a partition, 113a denotes a wall, 113b denotes a sealing part, 114 denotes a reaction space, 150 denotes a driving mechanism, 151 denotes a sun gear, 152 denotes a planetary gear, 153 denotes a planetary carrier, 154 denotes an outer gear, and 155 denotes an outer driving gear.

### DETAILED DESCRIPTION OF PREFERRED EMBODIMENTS

Structure

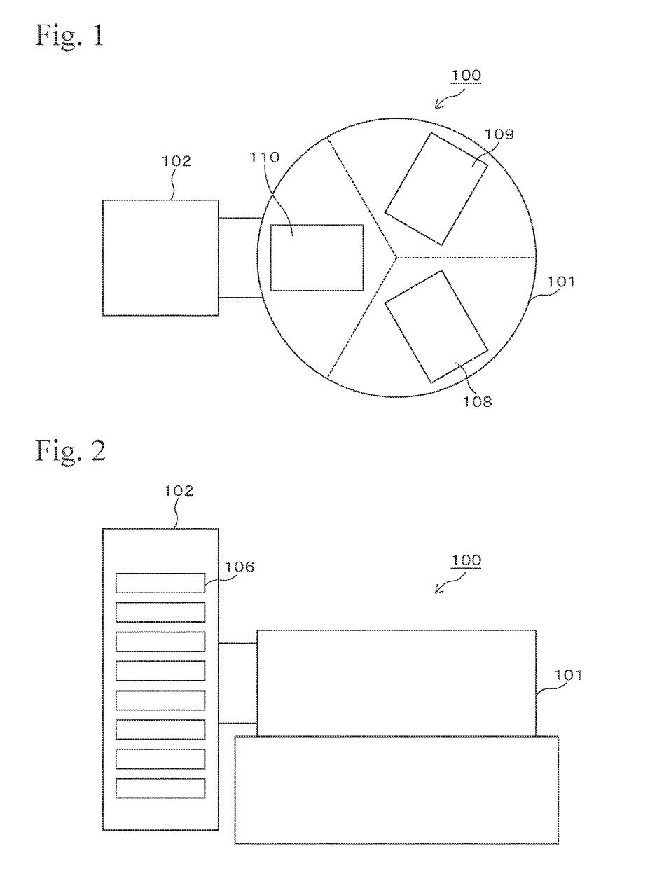

FIGS. 1 and 2 show a sputtering device 100 of an embodiment. The sputtering device 100 has a pressure-reducible container 101 and a load-lock chamber 102. The pressure-reducible container 101 is airtight and is configured so that its internal pressure is reduced by a vacuum pump (not shown). The load-lock chamber 102 connects to the pressure-reducible container 101 via a gate valve and has an airtight structure similar to that of the pressure-reducible container 101. The load-lock chamber 102 is also connected to a vacuum pump and is configured so that its internal pressure is controlled separately from the pressure-reducible container 101.

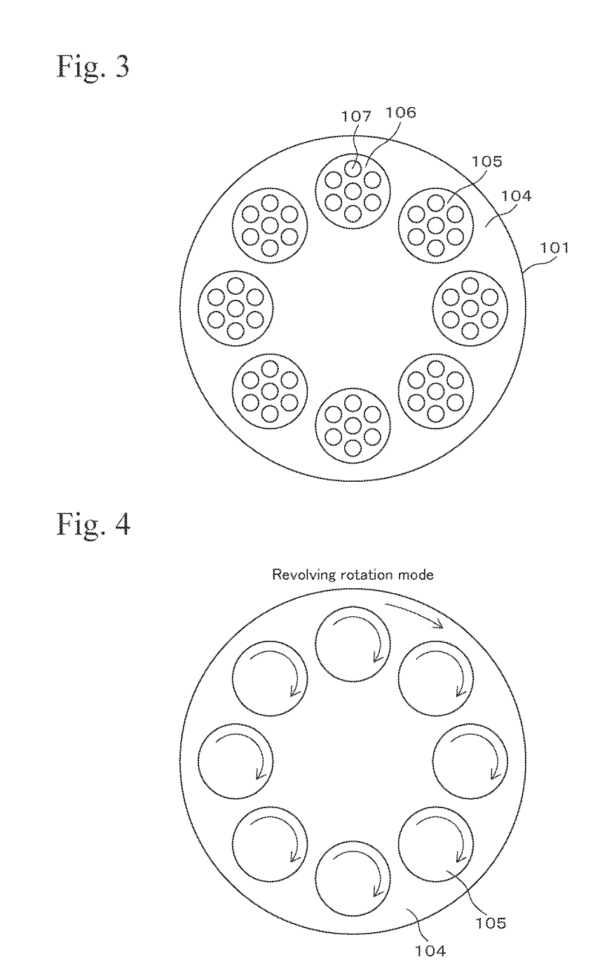

As shown in FIG. 3, the pressure-reducible container 101 has a revolution table 104 placed inside thereof. The revolution table 104 has eight rotation mounts 105 that are arranged on a circumference centered at the rotation center of the revolution table 104. The revolution table 104 and the rotation mounts 105 constitute a rotation and revolution table. The revolution table 104 and the rotation mounts 105 are rotatable independently from each other.

The rotation mounts 105 are approximately circular and rotate around its center. The rotation mounts 105 may rotate in a clockwise direction, in a counterclockwise direction, or in clockwise and counterclockwise directions, such as in a swinging manner. The rotations of the rotation mounts 105 are called “rotations” in the specification of the present invention. The rotation direction is specified as a direction as seen from above. The revolution table 104 is also approximately circular and rotates around its center. Rotation of the revolution table 104 makes the rotation mounts 105 revolve on the rotation center of the revolution table 104. The revolution table 104 may also rotate in a clockwise direction, in a counterclockwise direction, or in clockwise and counterclockwise directions, such as in a swinging manner.

The rotation mounts 105 are each configured so that a carrier 106 is arranged thereon. The carrier 106 holds workpieces 107 to be deposited, for example, holds optical parts, such as lenses. In this embodiment, the carrier 106 is able to accommodate seven workpieces 107. The workpieces 107 are not limited to optical parts. Although an exemplary case of depositing an optical thin film is described in this embodiment, the thin film to be deposited may be any type of coating film, including a metal film, an insulating film, and a semiconductor film.

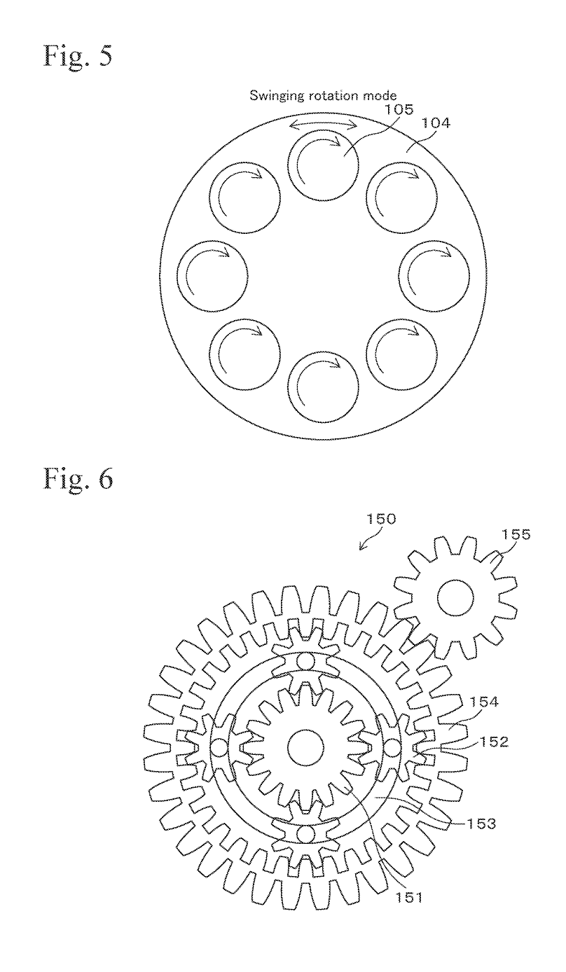

FIGS. 4 and 5 conceptually show operation states of the revolution table 104 and the rotation mounts 105. FIG. 4 shows a case of rotating the revolution table 104 and the rotation mounts 105 in the clockwise direction. The carriers 106 (refer to FIG. 3) on the rotation mounts 105 each rotate around the rotation centers of the respective rotation mounts 105 and each revolve around the rotation center of the revolution table 104. The mode shown in FIG. 4 is called a “revolving rotation mode”. The combination of the rotation direction and the revolution direction in the revolving rotation mode shown in FIG. 4 may be selected as desired. The combination of the rotation speed and the revolution speed may also be selected as desired.

FIG. 5 shows a case of rotating the revolution table 104 in the clockwise and counterclockwise directions in a swinging manner and rotating the rotation mounts 105 in the clockwise direction. The carriers 106 (refer to FIG. 3) on the rotation mounts 105 each rotate while swinging back and forth on their revolution orbit. The mode shown in FIG. 5 is called a “swinging rotation mode”. The combination of the swinging range, the swinging speed, the rotation direction, and the rotation speed in the swinging rotation mode shown in FIG. 5 may be selected as desired.

The following describes a driving mechanism for rotating the revolution table 104 and the rotation mounts 105. FIG. 6 shows a driving mechanism 150 constituting a driving system. The driving mechanism 150 is a planetary gear mechanism having a sun gear 151, four planetary gears 152, a planetary carrier 153, an outer gear 154, and an outer driving gear 155.

The sun gear 151 is driven and rotated by a first motor (not shown). The four planetary gears 152 engage with the sun gear 151 and are rotatably attached on the circular planetary carrier 153. Although four planetary gears 152 are described in FIG. 6 to simplify the drawing, eight planetary gears 152 may be used to correspond to the structure shown in FIG. 3.

The four planetary gears 152 engage with the circular outer gear 154 that is positioned at the outside of the four planetary gears 152. The outer gear 154 is formed with teeth at an inner circumferential side and an outer circumferential side, and its inside teeth engage with the four planetary gears 152 whereas its outside teeth engage with the outer driving gear 155. The outer driving gear 155 is driven and rotated by a second motor (not shown). The first motor for driving the sun gear 151 and the second motor for driving the outer driving gear 155 are rotatable independently from each other.

The rotation shaft of each of the planetary gears 152 connects with a rotation shaft serving as a rotation axis of the rotation mount 105 shown in FIG. 3, and thus, rotation of each of the planetary gears 152 makes the corresponding rotation mount 105 rotate. The revolution table 104 is fixed over the planetary carrier 153. Rotation of the planetary carrier 153 makes the revolution table 104 rotate, thereby making the rotation mounts 105 revolve. As described later, the movement mode of the rotation mounts 105 can be selected from (1) rotation without revolution, (2) revolution without rotation, (3) revolution and rotation (revolving rotation mode), and (4) swinging and rotation (swinging rotation mode).

The following describes a principle of independent control of the rotations of the rotation mounts 105 and the revolution table 104. Assuming that angular velocity and the number of teeth of the sun gear 151 are respectively represented by ωa and Za, angular velocity and the number of teeth of the planetary gear 152 are respectively represented by cob and Zb, angular velocity and the number of teeth of the outer gear 154 are respectively represented by ωc and Zc, and angular velocity of the planetary carrier 153 is represented by ωx, the following First Formula and Second Formula are satisfied on the basis of the fundamental principle of the planetary gear.

$$\begin{matrix}{ω}_{b} = {ω}_{x} - ( {ω}_{a} - {ω}_{x} ) \frac{{z}_{a}}{{z}_{b}} & First Formula \\ {ω}_{c} = {ω}_{x} - ( {ω}_{a} - {ω}_{x} ) \frac{{z}_{a}}{{z}_{c}} & Second Formula\end{matrix}$$

The rotation direction and the value of ωa are determined by driving control of the first motor. The rotation direction and the value of we are determined by driving control of the second motor.

The values of ωa and ωe are selected so that the value of ωx=0 in the First Formula and Second Formula, whereby the planetary gears 152 are rotated at the angular velocity cob without rotating the planetary carrier 153. Thus, the movement mode (1) is operated, and the rotation mounts 105 rotate without revolving.

The values of ωa and ωe are selected so that the value of ωb=0 in the First Formula and Second Formula, whereby the planetary carrier 103 is rotated at the angular velocity ωx without rotating the planetary gears 152. Thus, the movement mode (2) is operated, and the rotation mounts 105 revolve without rotating.

The values of ωa and ωe are selected so that the values of ωx and cob will not be zero in the First Formula and Second Formula, whereby the planetary gears 152 are rotated at the angular velocity ωb while the planetary carrier 103 is rotated at the angular velocity ωx. Thus, the movement mode (3) is operated, and the rotation mounts 105 rotate while revolving.

In the condition in which the values of ωx and cob are not zero, the value of cob may be set to be less than or greater than 1, and the values of wa and we may be controlled so that the value of ωx will periodically fluctuate to be positive or negative. In this case, the movement mode (4) is operated, and the rotation mounts 105 rotate while their rotation centers swing back and forth on their revolution orbit.

In the movement mode (1) or the movement mode (4), the value of cox may be controlled to move a specific rotation mount 105 or a specific carrier 106 to a desired position on the revolution orbit.

To return to FIG. 1, the sputtering device 100 also has a sputtering section 108, a sputtering section 109, and a plasma processing section 110. The sputtering section 108, the sputtering section 109, and the plasma processing section 110 are arranged on the revolution orbit of the rotation mounts 105. The sputtering section 108 and the sputtering section 109 have the same structure. The sputtering target is selected in accordance with a desired film to be deposited. For example, the sputtering section 108 may perform deposition of a first thin film, and the sputtering section 109 may perform deposition of a second thin film. Alternatively, the sputtering sections 108 and 109 may perform deposition of the same type of thin film.

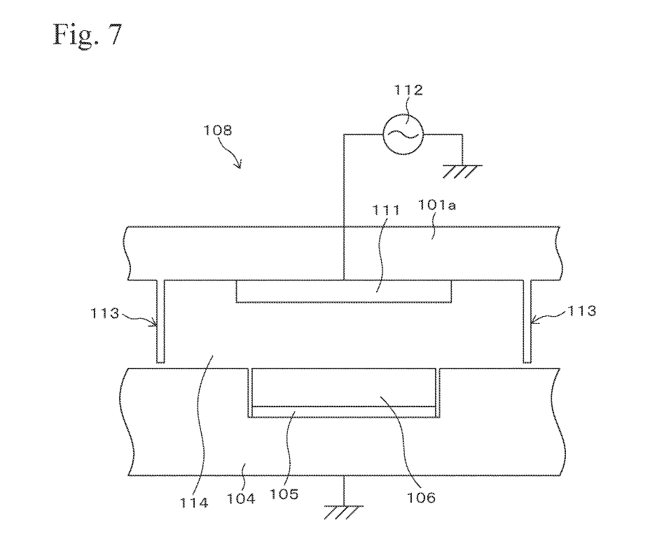

The following describes details of the sputtering sections 108 and 109. Since the sputtering sections 108 and 109 have the same structure, only the sputtering section 108 will be described here. FIG. 7 shows a sectional structure of the sputtering section 108. It is noted that FIG. 7 does not show the driving system, which is described by referring to FIG. 6.

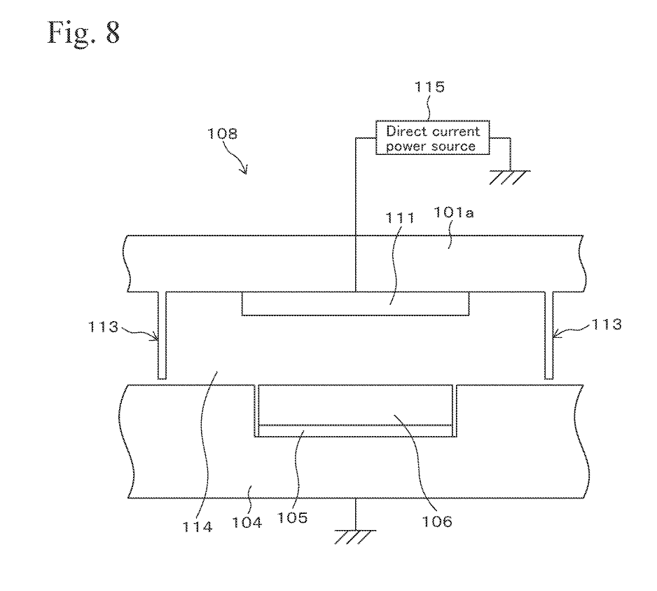

The sputtering section 108 has a sputtering target 111. The sputtering target 111 is attached on a back surface side of a top cover 101a of the pressure-reducible container 101. The sputtering target 111 connects to a high frequency power source 112. The sputtering section 108 may be configured to perform direct current (DC) sputtering, as shown in FIG. 8. In this structure, as shown in FIG. 8, a DC power source 115 is connected as a power source.

The carrier 106 is placed on the rotation mount 105 so as to face the sputtering target 111. As the revolution table 104 rotates, the carrier 106 also moves on the revolution orbit, and therefore, the carrier 106 may not be located at the position shown in FIG. 7. FIG. 7 shows a state in which the carrier 106 is stopped at the described position by controlling the value of ωx as described above. Although the carrier 106 has the workpieces 107 mounted thereon as shown in FIG. 2, the workpieces 107 are not shown in FIG. 7.

The top cover 101a is provided with partitions 113. The partitions 113 separate a film deposition atmosphere in a reaction space 114 from a film deposition atmosphere in an adjacent reaction space. The same or similar structure as the partitions 113 are also provided to the sputtering section 109 and the plasma processing section 110.

Sputtering film deposition may be performed by supplying gas of an element for sputtering, gas of an element to be reacted with a sputtered material, and other necessary gas, from a gas supplying system (not shown) into the reaction space 114. For example, a silicon compound film may be deposited. In this case, a silicon target is used as the sputtering target 111, and argon gas, oxygen gas, and nitrogen gas are supplied into the reaction space 114. Then, a vacuum pump (not shown) is started to reduce the pressure in the reaction space 114 to a desired degree. Next, the argon gas is ionized by high frequency electric power from the high frequency power source 112, and sputtering is performed. Thus, the material composing the sputtering target 111 is deposited on a surface of the respective workpieces 107 (refer to FIG. 3) arranged on the carrier 106 to generate a thin film. Meanwhile, the reactive gas reacts, and reactive sputtering is performed. The film deposition operation may also be performed in the sputtering section 109. The plasma processing section 110 has a radio frequency (RF) plasma source that generates RF plasma by high frequency discharging, and the plasma processing section 110 may perform etching treatment using plasma etching gas, film oxidizing treatment using oxygen plasma, or film nitriding treatment using nitrogen plasma. As an alternative to the plasma processing section 110, a structure using a radical source for supplying iron source may be configured to perform radical treatment.

The load-lock chamber 102 is configured to contain the workpieces 107 (refer to FIG. 3) arranged on the carrier 106. The workpieces 107 or the carrier 106 is moved between the load-lock chamber 102 and the pressure-reducible container 101 by a robot arm (not shown). As shown in FIG. 2, multiple carriers 106, on which the workpieces 107 are mounted, are stacked in a vertical direction and are contained in the load-lock chamber 102. The load-lock chamber 102 is provided with an elevator to vertically move the carrier 106.

First Exemplary Operation

An exemplary case of performing continuous film deposition in the movement mode (1) will be described hereinafter. In this case, a silicone oxide film is deposited as a first optical thin film on a lens in the sputtering section 108, and then a niobium oxide film is deposited as a second optical thin film in the sputtering section 109. The silicon oxide film of the first optical thin film and the niobium oxide film of the second optical thin film are alternately laminated in a multilayered manner to coat the lens, which is a workpiece, with a desired optical thin film.

First, a carrier 106 on which workpieces 107 (refer to FIG. 3) are mounted is placed on a rotation mount 105 shown in FIG. 4. The revolution table 104 is then rotated, and the first optical thin film is deposited on each of the workpieces 107 in the sputtering section 108 in a condition as shown in FIG. 7. After the first optical thin film is deposited, the revolution table 104 is rotated to move the carrier 106 into the sputtering section 109. Then, sputtering is performed while the rotation mount 105 rotates, to deposit the second optical thin film with respect to each of the workpieces 107 in the sputtering section 109.

The deposition of the first optical thin film and the deposition of the second optical thin film are alternately repeated “n” times. Consequently, a multilayered optical thin film is formed on each of the seven workpieces 107 (refer to FIG. 3) on the specific carrier 106 by alternately laminating “n” numbers of the silicon oxide films as the first optical thin films and the niobium oxide films as the second optical thin films.

The following processing steps are repeated during the above operation.

(1) While the film deposition is performed in the pressure-reducible container 101, eight carriers 106 holding seven untreated workpieces 107 are put in the load-lock chamber 102.
(2) The load-lock chamber 102 is then evacuated. During the film deposition in the pressure-reducible container 101, the gate valve is closed to separate the load-lock chamber 102 and the pressure-reducible container 101.
(3) After the film deposition is finished in the pressure-reducible container 101, the pressure in the pressure-reducible container 101 is set to be the same pressure in the load-lock chamber 102. Then, the gate valve separating the load-lock chamber 102 and the pressure-reducible container 101 is opened to enable moving out of the carrier 106 from the pressure-reducible container 101 to the load-lock chamber 102 and moving in a next carrier 106, on which workpieces 107 without films are mounted, from the load-lock chamber 102 to the pressure-reducible container 101. Thus, the treated workpieces 107 in the pressure-reducible container 101 are replaced with untreated workpieces 107 in the load-lock chamber 102.
(4) After the workpieces 107 are replaced, the gate valve is closed to separate the load-lock chamber 102 and the pressure-reducible container 101, and the untreated workpieces 107 are subjected to the film deposition treatment. During the film deposition treatment, the already-treated workpieces 107 in the load-lock chamber 102 are moved out to the outside of the device, and the processing step (1) is started.

The processing steps (1) to (4) are repeated, whereby the processing is continuously performed, and an optical thin film is formed on each of the workpieces 107 (lenses) with high productivity. The film deposition is performed in a small area immediately under the sputtering source, thereby enabling high speed film deposition.

Second Exemplary Operation

Batch processing for integrally treating multiple workpieces simultaneously will be described hereinafter. In this case, each of the carriers 106 is rotated while the revolution table 104 rotates at a constant rate. Each of the carriers 106 rotates while revolving. When a specific carrier 106 passes through the sputtering section 108, the film deposition of the first optical thin film is performed on workpieces 107 on the specific carrier 106. The specific carrier 106 then passes through the sputtering section 109, and meanwhile, the film deposition of the second optical thin film is performed. Thereafter, while the specific carrier 106 passes through the plasma processing section 110, the plasma treatment is performed. These three treatments are uniformly performed on each of the carriers 106 on the rotating revolution table 104. The sputtering sections 108 and 109 and the plasma processing section 110 may be controlled independently from each other or may be controlled at the same time. Such a structure enables depositing a mixed film made of target materials in the sputtering sections 108 and 109. Extremely thin films may be respectively deposited in the sputtering sections 108 and 109 and may be subjected to the plasma treatment at the same time.

The film deposition and the plasma treatment are repeated “n” times while the revolution table 104 rotates “n” times, whereby a multilayered optical thin film is formed on a surface of each of the workpieces 107 by alternately laminating “n” numbers of the silicon oxide films as the first optical thin films and the niobium oxide films as the second optical thin films. This processing enables integrally treating multiple workpieces uniformly at the same time and is thus called “batch processing”. The replacement of the workpieces 107 using the load-lock chamber 102 may be performed in the same manner as in the First Exemplary Operation.

Third Exemplary Operation

The movement mode (4) may be performed in the First Exemplary Operation and Second Exemplary Operation. In this case, when the carrier 106 and the sputtering target 111 have the positional relationship as shown in FIG. 7, the film deposition is performed while the revolution table 104 swings as shown in FIG. 5 and the rotation mount 105 rotates. The movement mode (4) is operated so that the rotation center will swing back and forth on the revolution orbit, and therefore, a highly uniform film is deposited.

Fourth Exemplary Operation

Although the same optical thin film is deposited on each of the workpieces 107 on the multiple carriers 106 in the First to Third Exemplary Operations, optical thin films having different optical characteristics from each other may be respectively deposited on the workpieces 106 on each carrier 106. The sputtering device 100 enables forming an optical thin film by alternately laminating the first optical thin films, which are deposited in the sputtering section 108, and the second optical thin films, which are deposited in the sputtering section 109. The optical characteristics are controlled by changing the thickness relationship between the first optical thin film and the second optical thin film in this method.

For example, a laminated layer having a first combination may be obtained in a first carrier 106, and a laminated layer having a second combination may be obtained in a second carrier 106. That is, optical thin films having different film quality from each other are respectively obtained in the carriers 106. The optical characteristics are controlled by adjusting one or more controlling elements such as a rotation speed of the revolution table 104, a swinging cycle, a swinging amplitude width, a rotation speed of the rotation mounts 105, sputtering discharge conditions, and a film deposition time. The sputtering device 100 is configured so that the revolution table 104 and the rotation mounts 105 are controllable independently from each other, and therefore, the film deposition condition is easily changed with respect to each of the carriers 106.

1. A sputtering device comprising:
a rotation and revolution table positioned in a pressure-reducible container and rotatable by independent control;
multiple sputtering targets placed on a revolution orbit of the rotation and revolution table so as to correspond to multiple workpieces to be set on the rotation and revolution table; and
a load-lock chamber through which the multiple workpieces are to be set on the rotation and revolution table,
wherein the rotation and revolution table is configured by arranging multiple rotation mounts on a revolution table, and the rotations of the revolution table and the multiple rotation mounts are independently controllable.

2. The sputtering device according to claim 1, wherein the multiple sputtering targets are configured to be used in respective film depositing atmospheres that are separated from each other in the pressure-reducible container.

3. The sputtering device according to claim 1, wherein the sputtering device performs sputtering while the rotation mounts rotate and the revolution table swings back and forth on the revolution orbit.

4. The sputtering device according to claim 1, wherein the sputtering device is configured so that multiple carriers on which workpieces are mounted are placed in the load-lock chamber and so that the multiple carriers are rotated and revolved in different manners.

5. The sputtering device according to claim 1, wherein the load-lock chamber is controlled independently from the pressure-reducible container so as to be reduced in pressure.

6. The sputtering device according to claim 1, further comprising:
a plasma source or a radical source provided on the revolution orbit of the rotation and revolution table, to perform plasma treatment or radical treatment on the multiple workpieces to be set on the rotation and revolution table.

7. The sputtering device according to claim 2, wherein the sputtering device performs sputtering while the rotation mounts rotate and the revolution table swings back and forth on the revolution orbit.

8. The sputtering device according to claim 2, wherein the sputtering device is configured so that multiple carriers on which workpieces are mounted are placed in the load-lock chamber and so that the multiple carriers are rotated and revolved in different manners.

9. The sputtering device according to claim 3, wherein the sputtering device is configured so that multiple carriers on which workpieces are mounted are placed in the load-lock chamber and so that the multiple carriers are rotated and revolved in different manners.

10. The sputtering device according to claim 2, wherein the load-lock chamber is controlled independently from the pressure-reducible container so as to be reduced in pressure.

11. The sputtering device according to claim 3, wherein the load-lock chamber is controlled independently from the pressure-reducible container so as to be reduced in pressure.

12. The sputtering device according to claim 4, wherein the load-lock chamber is controlled independently from the pressure-reducible container so as to be reduced in pressure.

13. The sputtering device according to claim 2, further comprising:
a plasma source or a radical source provided on the revolution orbit of the rotation and revolution table, to perform plasma treatment or radical treatment on the multiple workpieces to be set on the rotation and revolution table.

14. The sputtering device according to claim 3, further comprising:
a plasma source or a radical source provided on the revolution orbit of the rotation and revolution table, to perform plasma treatment or radical treatment on the multiple workpieces to be set on the rotation and revolution table.

15. The sputtering device according to claim 4, further comprising:
a plasma source or a radical source provided on the revolution orbit of the rotation and revolution table, to perform plasma treatment or radical treatment on the multiple workpieces to be set on the rotation and revolution table.

16. The sputtering device according to claim 5, further comprising:
a plasma source or a radical source provided on the revolution orbit of the rotation and revolution table, to perform plasma treatment or radical treatment on the multiple workpieces to be set on the rotation and revolution table.
